(19) United States
(12) Patent Application Publication
(10) Pub. No.: US 2026/0362692 A1
(43) Pub. Date: Nov. 12, 2026

(54) SEMICONDUCTOR MEMORY DEVICES WITH CHANNEL PATTERNS

(71) Applicant: Samsung Electronics Co., Ltd., Suwon-si (KR)

(72) Inventor: YONG-HOON SON, Suwon-si (KR)

(21) Appl. No.: 19/566,314

(22) Filed: Mar. 13, 2026

(30) Foreign Application Priority Data
May 7, 2025 (KR) 10-2025-0059014

(51) Int. Cl. H10B 43/10; G11C 5/06; G11C 16/04; H10B 41/10; H10B 41/27; H10B 41/35; H10B 41/41; H10B 43/27; H10B 43/35; H10B 43/40; H10D 30/68; H10D 30/69; H10D 62/17; H10D 64/27; H10D 30/01

(52) U.S. Cl. CPC H10B 43/10; G11C 5/063; G11C 16/0483; H10B 41/10; H10B 41/27; H10B 41/35; H10B 41/41; H10B 43/27; H10B 43/35; H10B 43/40; H10D 30/689; H10D 30/6891; H10D 30/693; H10D 30/697; H10D 62/292; H10D 64/514; H10D 64/519; H10D 30/0411; H10D 30/0413

(57) ABSTRACT

A semiconductor memory device includes a substrate, channel layers stacked along a first direction perpendicular to a top surface of the substrate, each of the channel layers including a plurality of channel patterns connected to each other in a second direction parallel to the top surface of the substrate, each of the channel patterns having at least three rounded surfaces, a plurality of gate electrodes penetrating the channel layers in the first direction, the gate electrodes adjacent to the rounded surfaces of the channel patterns, respectively, and data storage patterns interposed between the gate electrodes and the channel patterns.

### CROSS-REFERENCE TO RELATED APPLICATIONS

This U.S. non-provisional patent application claims priority under 35 U.S.C. §119 to Korean Patent Application No. 10-2025-0059014 filed on May 7, 2025, in the Korean Intellectual Property Office, the entire contents of which are hereby incorporated by reference.

### BACKGROUND

An electronic system required to store data may require a semiconductor device capable of storing higher-capacity data. Accordingly, research is being conducted on methods for increasing data storage capacity of semiconductor devices. For example, as one of the methods for increasing the data storage capacity of the semiconductor device, a semiconductor device including memory cells three-dimensionally arranged, instead of two-dimensionally arranging the memory cells, has been proposed.

### SUMMARY

Some aspects of the present disclosure provide semiconductor memory devices with improved reliability and integration. Other advantages provided by the present disclosure may be clearly understood from the following description by those skilled in the art.

According to some implementations of the present disclosure, a semiconductor memory device includes a substrate, channel layers stacked along a first direction perpendicular to a top surface of the substrate, each of the channel layers including a plurality of channel patterns connected to each other in a second direction parallel to the top surface of the substrate, each of the channel patterns having at least three rounded surfaces, a plurality of gate electrodes penetrating the channel layers in the first direction, the gate electrodes adjacent to the rounded surfaces of the channel patterns, respectively, and data storage patterns interposed between the gate electrodes and the channel patterns.

According to some implementations of the present disclosure, a semiconductor memory device includes a substrate, a stack comprising channel layers stacked along a first direction perpendicular to a top surface of the substrate and spaced apart from each other in a second direction parallel to the top surface of the substrate, a plurality of gate electrodes penetrating the channel layers of the stack in the first direction, and a data storage pattern interposed between the gate electrodes and the channel layers. The stack includes interlayer insulating layers respectively interposed between the adjacent channel layers in the first direction, and sacrificial patterns respectively interposed between the adjacent channel layers in the second direction. Each of the channel layers includes a plurality of channel patterns connected to each other in a third direction parallel with a top surface of the substrate, each of the channel patterns having at least three rounded surfaces. The gate electrodes are adjacent the rounded surfaces in the respective channel patterns.

According to some implementations of the present disclosure, a semiconductor memory device includes a substrate, channel layers stacked along a first direction perpendicular to a top surface of the substrate and spaced apart from each other in a second direction parallel to the top surface of the substrate, each of the channel layers including a plurality of channel patterns connected to each other in a third direction parallel to the top surface of the substrate and each of the plurality of channel patterns having first, second, third, and fourth rounded surfaces arranged in different directions, sacrificial patterns respectively interposed between the adjacent channel layers in the second direction, interlayer insulating layers respectively interposed between the adjacent channel layers in the first direction and between the sacrificial patterns, first, second, third, and fourth gate electrodes penetrating each of the channel patterns in the first direction, wherein the first to fourth gate electrodes are adjacent to the first, second, three, and fourth rounded surfaces of the channel patterns, respectively, data storage patterns interposed between the first to fourth gate electrodes and the channel patterns, a vertical insulating pattern that insulates the first to fourth gate electrodes within the respective channel patterns, bit lines respectively connected to the first ends of the channel layers, and a common source line commonly connected to the second ends of the channel layers.

### BRIEF DESCRIPTION OF THE DRAWINGS

FIG. 1 is a circuit diagram of an example of a memory cell array of a semiconductor memory device.

FIGS. 2 and 3 are plan views of an example of a semiconductor memory device.

FIG. 4 is a cross-sectional view taken along a line A-A′ of FIG. 2.

FIG. 5 is a cross-sectional view taken along a line B-B’ of FIG. 2.

FIGS. 6A and 6B are enlarged views of a ‘P1’ portion of FIG. 3.

FIG. 7 is an enlarged view of a ‘P2’ portion of FIG. 5.

FIG. 8 is a schematic plan view of an example of a semiconductor memory device.

FIG. 9 is an enlarged view of a ‘P3’ portion of FIG. 8.

FIG. 10 is a schematic plan view of an example of a semiconductor memory device.

FIG. 11 is an enlarged view of a ‘P4’ portion of FIG. 10.

FIGS. 12A, 12B, and 12C are diagrams illustrating an example of a method of operating a semiconductor device.

FIGS. 13A, 14A, 15A, 16A, 17A, and 18A are plan views illustrating an example of a method of manufacturing a semiconductor memory device.

FIGS. 13B, 14B, 15B, 16B, 17B, and 18B are cross-sectional views taken along lines A-A′ of FIGS. 13A - 18A, respectively.

FIGS. 13C, 14C, 15C, 16C, 17C, and 18C are cross-sectional views taken along lines B-B′ of FIGS. 13A - 18A, respectively.

### DETAILED DESCRIPTION

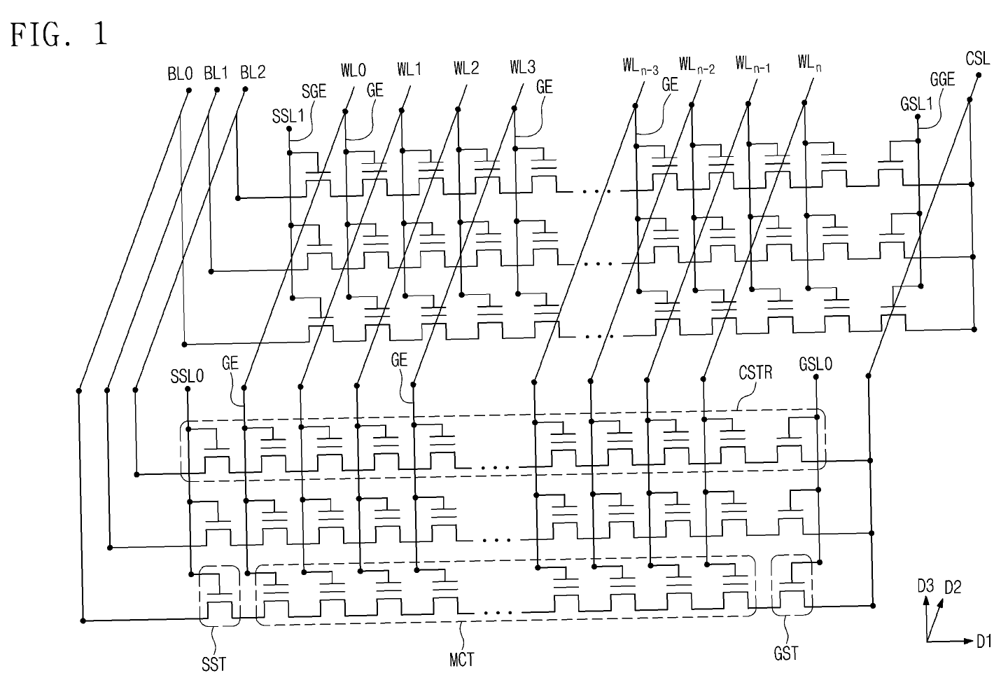

FIG. 1 is a circuit diagram illustrating an example of a memory cell array of a semiconductor memory device. Referring to FIG. 1, a semiconductor memory device may include bit lines BL0, BL1, and BL2, a common source line CSL, word lines WL0 to WLn, string selection lines SSL0 and SSL1, ground selection lines GSL0 and GSL1, and memory cell strings CSTR between the bit lines BL0-BL2 and the common source line CSL.

Each of the cell strings CSTR may include a plurality of memory cell transistors MCT connected in series in a first direction D1. In addition, each of the cell strings CSTR may include a string selection transistor SST connected between the corresponding bit line BL0-BL2 and the memory cell transistor MCT and a ground selection transistor GST connected between the common source line CSL and the memory cell transistor MCT.

The cell strings CSTR may be arranged along a second direction D2 and a third direction D3. Here, the second direction D2 may be perpendicular to the first direction D1, and the third direction D3 may be perpendicular to first and second directions D1 and D2. The cell strings CSTR may be connected in parallel to each of the bit lines BL0-BL2. The cell strings CSTR two-dimensionally arranged may be commonly connected to the common source line CSL. The cell strings CSTR arranged along the third direction D3 may be respectively connected to different bit lines BL0-BL2.

The common source line CSL may be commonly connected to the ground selection transistors GST.

In each cell string CSTR, the memory cell transistors MCT may be controlled by a plurality of word lines WL0-WLn, respectively. Gate electrodes GE of the memory cell transistors MCT located at the same distance from the common source line CSL may be commonly connected to one of the word lines WL0-WLn. In addition, each of the memory cell transistors MCT may include a data storage element.

The string selection transistor SST of each cell string CSTR may be controlled by the string selection lines SSL0 and SSL1, and the ground selection transistor GST may be controlled by corresponding ground selection lines GSL0 and GSL1.

The string selection gate electrodes SGE of the string selection transistors SST arranged along the third direction D3 may be connected to the string selection lines SSL0 and SSL1. The ground selection gate electrodes GGE of the ground selection transistors GST arranged along the third direction D3 may be connected to the ground selection lines GSL0 and GSL1.

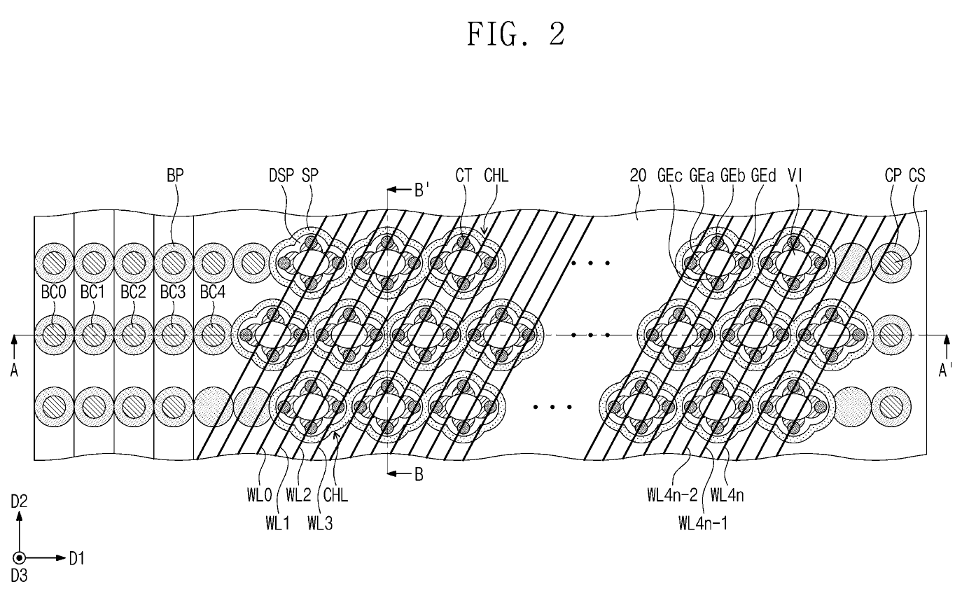

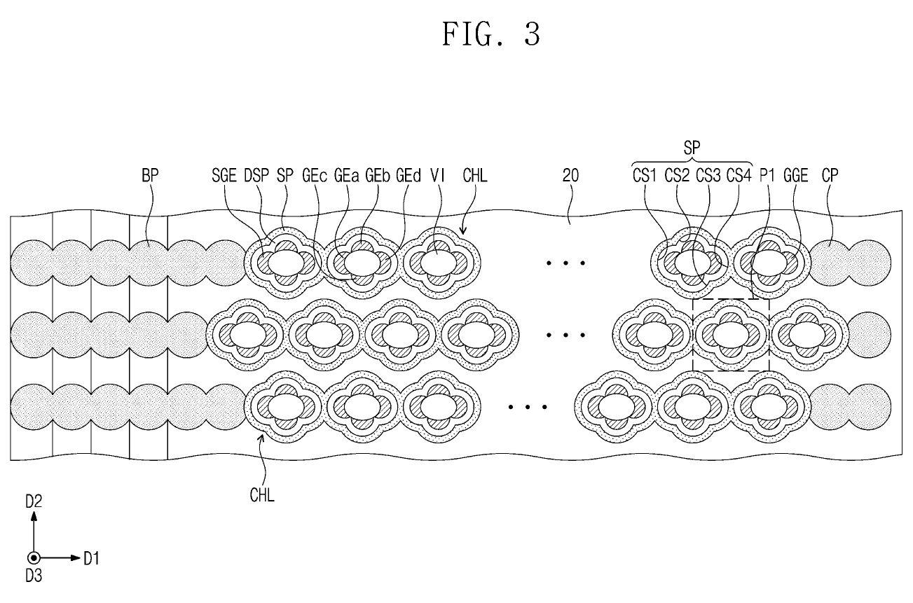

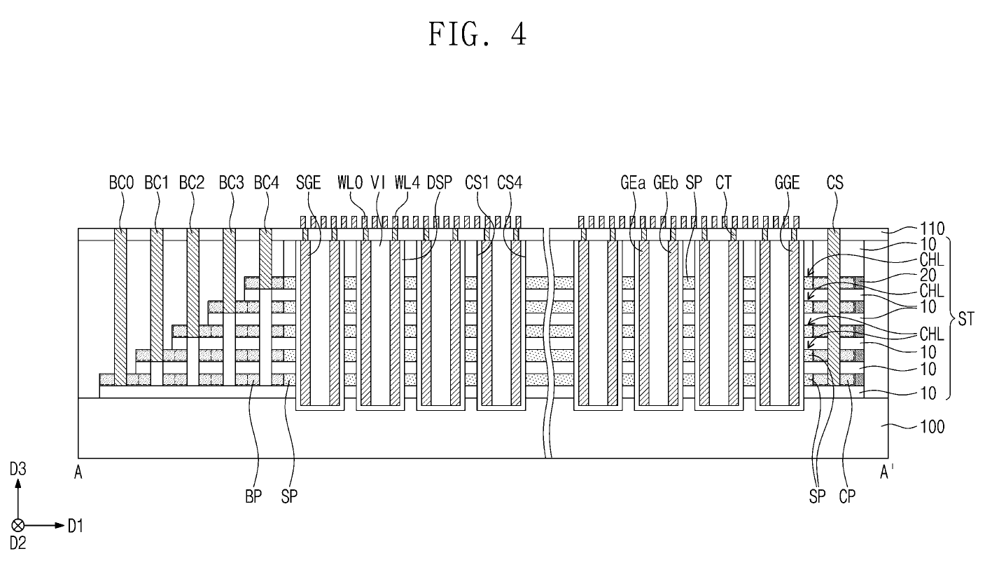

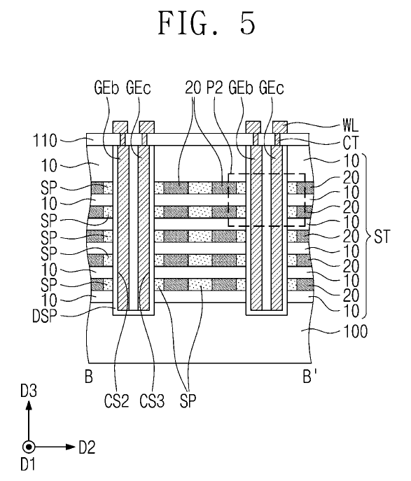

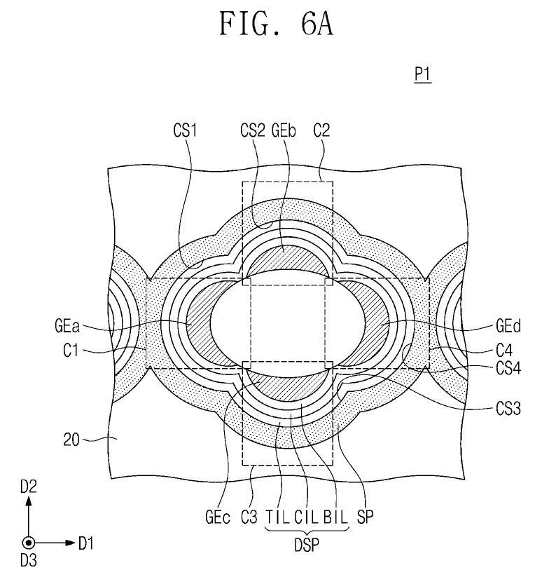

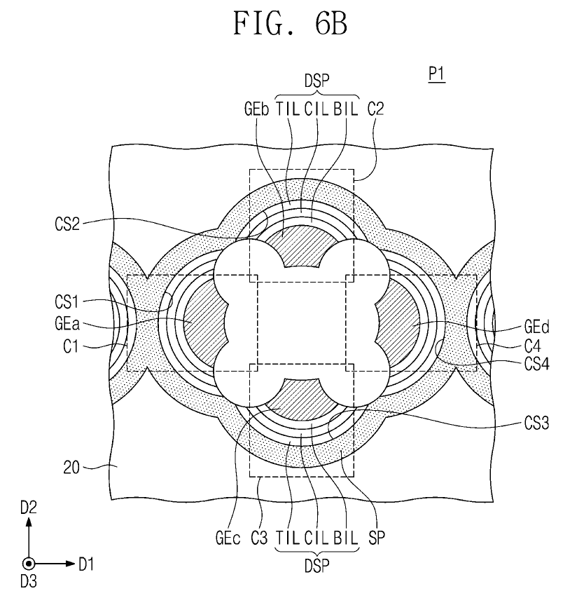

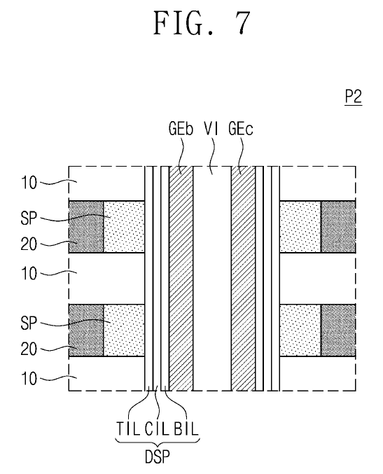

FIGS. 2 and 3 are plan views of an example of a semiconductor memory device. FIG. 4 is a cross-sectional view taken along a line A-A′ of FIG. 2. FIG. 5 is a cross-sectional view taken along a line B-B’ of FIG. 2. FIGS. 6A and 6B are enlarged views of a ‘P1’ portion of FIG. 3. FIG. 7 is an enlarged view of a ‘P2’ portion of FIG. 5.

Referring to FIGS. 2, 3, 4, and 5, a stack ST including vertically stacked channel layers CHL may be disposed on a substrate 100.

The substrate 100 may be one of a material having semiconductor characteristics (for example, a silicon wafer), an insulating material (for example, glass), a semiconductor covered with the insulating material, or a conductor. For example, the substrate 100 may be a silicon wafer having a first conductivity type.

Each of the channel layers CHL may extend along a first direction D1 parallel to the top surface of the substrate 100. The channel layers CHL disposed at the same distance from the top surface of the substrate 100 may be arranged to be spaced apart in the second direction D2 that is parallel to the top surface of the substrate 100 and intersects the first direction D1.

According to some implementations, each of the channel layers CHL may include a plurality of channel patterns SP connected to each other in the first direction D1 parallel to the top surface of the substrate 100.

Each of the channel patterns SP may have at least three or more rounded surfaces CS1, CS2, CS3, and CS4. For example, referring to FIGS. 6A and 6B, each of the channel patterns SP may have a first rounded surface CS1, a second rounded surface CS2, a third rounded surface CS3, and a fourth rounded surface CS4. The first to fourth rounded surface surfaces CS1 to CS4 of each channel pattern SP may protrude or protrude in different directions.

In some implementations, the first and fourth rounded surfaces CS1 and CS4 may be disposed to be symmetrical to each other in the first direction D1 (for example, symmetrical with respect to an imaginary line in the second direction D2), and the second and third rounded surfaces CS2 and CS3 may be disposed to be symmetrical to one another in the second direction D2 (for example, symmetrical with respect to an imaginary line in the first direction D1). The first and fourth rounded surfaces CS1 and CS4 of the channel patterns SP adjacent to each other in the first direction D1 may be connected to each other.

In each channel pattern SP, the distance between the first rounded surface CS1 and the fourth rounded surface CS4 in the first direction D1 may be different from the distance between the second rounded surface CS2 and the third rounded surface CS3 in the second direction D2. Each channel pattern SP may have a first width in the first direction D1 and may have a second width smaller than the first width in the second direction D2.

The channel patterns SP constituting each channel layer CHL may have a substantially uniform thickness in the horizontal direction. In some implementations, since the channel patterns SP constituting each channel layer CHL are formed at the same time, a boundary between the channel patterns SP may not be observed.

The channel patterns SP may include at least one of a semiconductor layer that is not doped with impurities or that is doped with impurities, a silicide layer, and a metal layer. For example, the channel patterns SP may include an impurity-doped polycrystalline silicon layer of the first conductivity type.

For example, the channel patterns SP may include an oxide semiconductor material. For example, the oxide semiconductor material may include at least one of indium (In), gallium (Ga), zinc (Zn), or tin (Sn). For example, the oxide semiconductor may include InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, InₓGa_{y}O, or a combination thereof. In some implementations, the channel patterns SP may include Indium Gallium Zinc Oxide (IGZO). The channel patterns SP may include a single layer or multiple layers of the oxide semiconductor. The channel patterns SP may include an amorphous, crystalline, or polycrystalline oxide semiconductor.

The stack ST may include sacrificial patterns 20 and interlayer insulating layers 10 layer. The sacrificial patterns 20 may isolate the channel layers CHL in the second direction. The interlayer insulating layers 10 may isolate the channel layers CHL in the third direction D3 and be between the sacrificial patterns 20 adjacent to each other in the third directions D3. The sacrificial patterns 20 may be disposed at substantially the same level as the channel layers CHL from the top surface of the substrate 100. The sacrificial patterns 20 may be in direct contact with the second and third rounded surfaces CS2, CS3 of the channel patterns SP.

The interlayer insulating layers 10 may include a silicon oxide layer and/or a low-k dielectric layer. The lowermost interlayer insulating layer 10 among the interlayer insulating layers 10 may be in contact with the top surface of the substrate 100.

The sacrificial patterns 20 may include an insulating material having etch selectivity with respect to the interlayer insulating layers 10. For example, the interlayer insulating layers 10 may be silicon oxide layers, and the sacrificial patterns 20 may include at least one of silicon nitride layers, silicon oxynitride layers, polycrystalline silicon layers, or metal layers. For example, the interlayer insulating layers 10 may include a silicon oxide layer, and the sacrificial patterns 20 may include a silicon nitride layer.

Each channel layer CHL may have a first end and a second end opposite to the first end in the first direction D1. The first end of each channel layer CHL may be connected to the bit line pad pattern BP, and the second end of each channel layer CHL may be connected to the common source pad pattern CP.

The bit line pad patterns BP may include an impurity-doped semiconductor material, and may be in contact with and connected to the channel pattern SP. The bit line pad patterns BP may have rounded sidewalls like the channel patterns SP.

The bit line pad patterns BP may decrease in length in the first direction D1 of the bit line pad patterns as the distance from the top surface of the substrate 100 increases. In other words, the bit line pad patterns BP may be stacked in a step shape. The bit line pad patterns BP may be stacked through the interlayer insulating layers 10 in the third direction D3, and may be in contact with the sacrificial patterns 20 in the second direction D2.

The common source pad patterns CP may be stacked to vertically overlap each other. The common source pad patterns CP may include an impurity-doped semiconductor material, and may be in contact with and connected to the channel pattern SP. The common source pad patterns CP may have rounded sidewalls like the channel patterns SP.

A plurality of gate electrodes SGE, GEa, GEb, GEc, GEd, and GGE may be disposed on the substrate 100 and may vertically penetrate the vertically stacked channel layers CHL. The gate electrodes SGE, GEa to GEd, and GGE may penetrate each channel pattern SP in the third direction D3. In some implementations, each of the channel layers CHL may have a substantially uniform thickness and surround portions of the gate electrodes SGE, GEa to GEd, GGE.

The gate electrodes SGE, GEa to GEd, and GGE may be adjacent to the rounded surfaces CS1, CS2, CS3, and CS4 of the channel patterns SP, respectively. Each of the gate electrodes SGE, GEa to GEd, and GGE may have a rounded sidewall. Each of the gate electrodes SGE, GEa to GEd, and GGE may have an outer surface adjacent to a data storage pattern DSP and an inner surface in contact with a vertical insulating pattern VI, and the outer surface and the inner surface may have a rounded shape.

The gate electrodes SGE, GEa to GEd, and GGE may include at least one of conductive materials (e.g., a doped semiconductor, a metal, a conductive metal nitride, a silicide, or a nanostructure (such as a carbon nanotube or graphene)).

A gate electrode adjacent to the first end of each channel layer CHL among the gate electrodes SGE, GEa to GEd, and GGE may be used as a string selection gate electrode SGE, and a gate electrode adjacent to a second end of each channel layer CHL among the gate electrodes SGE, GEa to GEd, and GGE may be used for a ground selection gate electrode GGE. In addition, gate electrodes GEa to GEd other than the string selection gate electrode SGE and the ground selection gate electrode GGE may be gate electrodes of memory cell transistors (MCT in FIG. 2).

In detail, referring to FIGS. 6A and 6B, the first to fourth gate electrodes GEa to GEd may penetrate each channel pattern SP in the third direction D3. The first to fourth gate electrodes GEa to GEd may be adjacent to the first to fourth rounded surfaces CS1, CS2, CS3, and CS4 of each channel pattern SP, respectively. The first to fourth gate electrodes GEa to GEd may each have substantially the same radius of curvature as the first to fourth rounded surfaces CS1, CS2, CS3, and CS4 of each channel pattern SP. The first gate electrode GEa may be spaced apart from the fourth gate electrode GEd in the first direction D1, and the second gate electrode GEb may be spaced apart from the third gate electrode GEc in the second direction D2.

The first to fourth gate electrodes GEa to GEd extend in the third direction D3 on the substrate 100 and may be separated and spaced apart from each other by the vertical insulating pattern VI.

The vertical insulating pattern VI may penetrate each channel pattern SP in the third direction D3. The vertical insulating pattern VI may include, for example, a silicon oxide layer, a silicon nitride layer, a silicon oxynitride layer, and/or a low dielectric layer.

The data storage patterns DSP may be disposed between the channel patterns SP and the gate electrodes GEa to GEd. Each data storage pattern DSP may cover outer sidewalls and bottom surfaces of the gate electrodes GEa to GEd with a substantially uniform thickness. The data storage pattern DSP may extend in a direction perpendicular to the top surface of the substrate 100. The data storage patterns DSP may extend along the third direction D3 between the channel layers CHL and the gate electrodes GEa to GEd on the top surface of the substrate 100.

Referring to FIGS. 6A and 7, the data storage patterns DSP may penetrate the channel patterns SP in the third direction D3, respectively. As another example, referring to FIGS. 6B and 7, the plurality of data storage patterns DSP may be in contact with the first to fourth rounded surfaces CS1 to CS4 of each channel pattern SP, and may be spaced apart from each other by the vertical insulating pattern VI.

The data storage patterns DSP may include a single layer or a plurality of thin layers. In some implementations, the data storage patterns DSP may include a charge storage layer that stores data in a NAND flash memory device.

For example, referring to FIGS. 6A, 6B, and 7, the data storage patterns DSP may include a tunnel insulating layer TIL, a charge storage layer CIL, and a blocking insulating layer BIL sequentially stacked on the first to fourth rounded surfaces CS1 to CS4 of each channel pattern SP. The tunnel insulating layer TIL may be in contact with the first to fourth rounded surfaces CS1 to CS4 of the channel patterns SP, and the blocking insulating layer BIL may be adjacent to the outer sidewalls of the gate electrodes GEa to GEd. The charge storage layer CIL may be interposed between the tunnel insulating layer TIL and the blocking insulating layer BIL.

The charge storage layer CIL may be, for example, a trap insulating layer, a floating gate electrode, or an insulating layer including conductive nano dots. The charge storage layer CIL may include at least one of a silicon nitride layer, a silicon oxynitride layer, silicon-rich nitride, nanocrystalline silicon, or a laminated trap layer.

The tunnel insulating layer TIL may be a material having a band gap larger than that of the charge storage layer CIL, and may be, for example, a silicon oxide layer.

The blocking insulating layer BIL may be a material having a band gap smaller than that of the tunnel insulating layer TIL and larger than that of the charge storage layer CIL. The blocking insulating layer BIL may be, for example, a high-k dielectric layer such as an aluminum oxide layer and a hafnium oxide layer.

In some implementations, the data storage patterns DSP may include a ferroelectric material. The ferroelectric material may consist of a dielectric material comprising hafnium. The ferroelectric material may include, for example, HfO₂, HfSiO₂ (Si-doped HfO₂), HfAlO₂ (Al-doped HfO₂), HfSiON, HfZnO, HfZrO2, ZrO2, ZrsSiO2, HfZrSiO2, ZrSiON, LaAlO, HfDyO₂, or HfScO₂.

In some implementations, the data storage patterns DSP may include a thin layer for phase change memory or a thin layer for variable resistance memory. The data storage patterns DSP may include, for example, perovskite compounds, transition metal oxide, phase-change material, magnetic materials, ferromagnetic materials, or antiferromagnetic materials.

Referring to FIGS. 6A and 6B, the first gate electrode GEa, a first portion of the channel pattern SP adjacent to the first gate electrode GEa, and the data storage pattern DSP may constitute the first memory cell C1. The second gate electrode GEb, a second portion of the channel pattern SP adjacent to the second gate electrode GEb, and the data storage pattern DSP may constitute the second memory cell C2. The third gate electrode GEc, a third portion of the channel pattern SP adjacent to the third gate electrode GEc, and the data storage pattern DSP may constitute the third memory cell C3. The fourth gate electrode GEd, a fourth portion of the channel pattern SP adjacent to the fourth gate electrode GEd, and the data storage pattern DSP may constitute the fourth memory cell C4. The first to fourth memory cells C1 to C4 may constitute each cell string CSTR described with reference to FIG. 1.

Referring to FIGS. 2, 4, and 5, word lines WL0 to WL4n may be disposed on the insulating layer 110 covering the stack ST and the gate electrodes SGE, GEa to GEd, and GGE. The word lines WL0 to WL4n may extend side by side in a direction parallel to the top surface of the substrate 100 and diagonal to (or intersecting with) the first and second directions D1 and D2.

Each of the word lines WL0 to WL4n may be respectively connected to the gate electrodes GEa to GEd arranged along the oblique direction through the word line contact CT. As an example, a first word line WL0 may be connected to first gate electrodes GEa, a second word line WL1 may be connected to second gate electrodes GEb, a third word line WL2 may be connected to third gate electrodes GEc, and a fourth word line WL3 may be connected to fourth gate electrodes GEd. Bit line contacts BC0, BC1, BC2, BC3, and BC4 may be connected to the bit line pad patterns BP. The bit line contacts BC0, BC1, BC2, BC3, and BC4 may have different vertical lengths in the third direction D3.

The common source contacts CS may vertically penetrate the common source pad patterns CP. Sidewalls of the vertically overlapping common source pad patterns CP may contact each common source contact CS.

The bit line contacts BC0 to BC4 and the common source contacts CS may be formed of at least one conductive material. The bit line contacts BC0 to BC4 and the common source contacts CS may include a conductive layer for ohmic contact with the bit line pad patterns BP and the common source pad patterns CP. The bit line contacts BC0 to BC4 and the common source contacts CS may include at least one of a doped silicon layer, metal layers, silicide layers, or metal nitride layers.

According to some implementations, channels may be formed by inverting the channel patterns SP adjacent to the gate electrodes SGE, GEa to GEd, and GGE by an operating voltage applied to the gate electrodes GGE. Channels induced by gate electrodes SGE, GEa to GEd, and GGE adjacent to each other may overlap or be connected to each other. For example, channels of the memory cell transistors may be connected to each other to form a current path between the bit lines BL0 to BL2 and the common source line CSL.

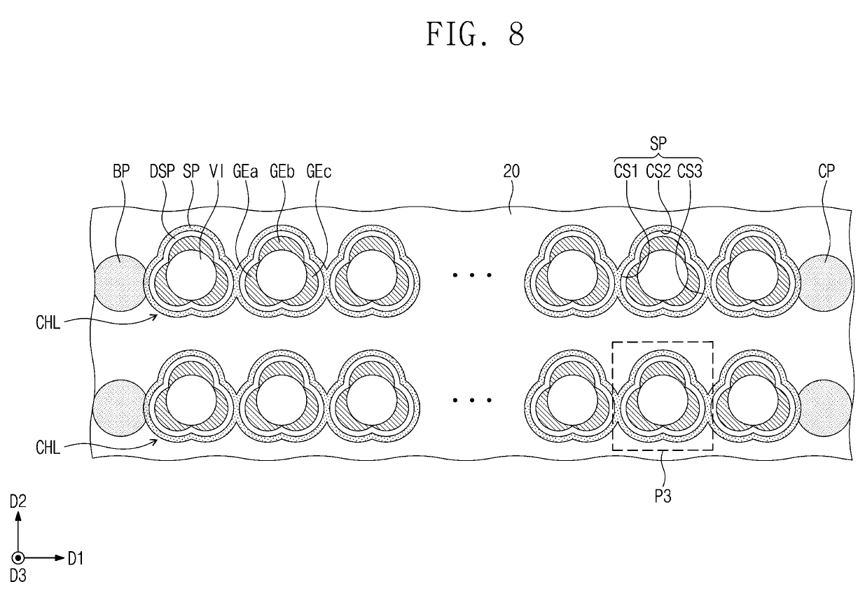

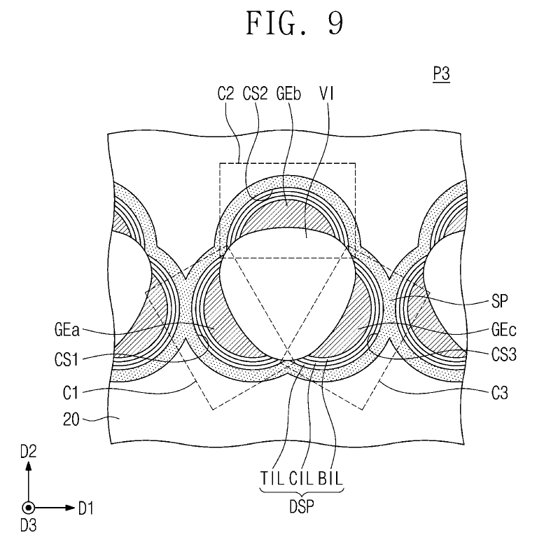

FIG. 8 is a schematic plan view of an example of a semiconductor memory device. FIG. 9 is an enlarged view of the P3 portion of FIG. 8. For concise description, description of the same technical features as the semiconductor memory devices described with respect to FIGS. 2 - 5, 6A, 6B, and 7 may be omitted from the following description, and the following discussion focuses on technical features that differ from that of the semiconductor memory devices described with respect to FIGS. 2 to 5, 6A, 6B, and 7.

Referring to FIGS. 8 and 9, as described above, the interlayer insulating layers 10 and the channel layers CHL may be alternately stacked along the third direction D3 perpendicular to the top surface of the substrate 100. The sacrificial patterns 20 may be disposed between the channel layers CHL adjacent to each other in the second direction D2.

Each of the channel layers CHL may include a plurality of channel patterns SP connected to each other in the first direction D1. Each of the channel patterns SP may surround portions of sidewalls of the plurality of gate electrodes GEa to GEc.

For example, each of the channel patterns SP may have a first rounded surface CS1, or an outer sidewall, a second rounded surface CS2, and a third rounded surface CS3. The first, second, and third rounded surfaces CS1, CS2, and CS3 may be arranged in different directions when viewed in a plan view. The first, second, and third rounded surfaces CS1, CS2, and CS3 may have substantially the same radius of curvature.

The data storage pattern DSP, the first, second, and third gate electrodes GEa, GEb, and GEc, and the vertical insulating pattern VI may be disposed in respective vertical holes penetrating the interlayer insulating layers 10 and the channel layers CHL alternately stacked on the substrate 100.

Referring to FIG. 9, one channel pattern SP and the first, second, and third gate electrodes GEa, GEb, and GEc may constitute the first, second and third memory cells C1, C2, and C3.

The first, second, and third gate electrodes GEa, GEb, and GEc may penetrate each channel pattern SP in the third direction D3. The first, second, and third gate electrodes GEa, GEb, and GEc may be disposed adjacent to the first, second, or third rounded surfaces CS1, CS2, and CS3 of each channel pattern SP, respectively. The first, second, and third gate electrodes GEa, GEb, and GEc may have rounded outer sidewalls. The channel patterns SP of each channel layer CHL may have a uniform thickness and surround the rounded outer sidewalls of the first, second, and third gate electrodes GEa, GEb, and GEc.

The data storage patterns DSP may be disposed between the first, second, and third gate electrodes GEa, GEb, and GEc and the first, second and third rounded surfaces CS1, CS2, and CS3 of each channel pattern SP, respectively. Each data storage pattern DSP may be in contact with a corresponding rounded side surface of each channel pattern SP and an outer sidewall of a corresponding gate electrode.

The vertical insulating pattern VI may insulate and separate the first, second, and third gate electrodes GEa, GEb, and GEc from each other in each channel pattern SP.

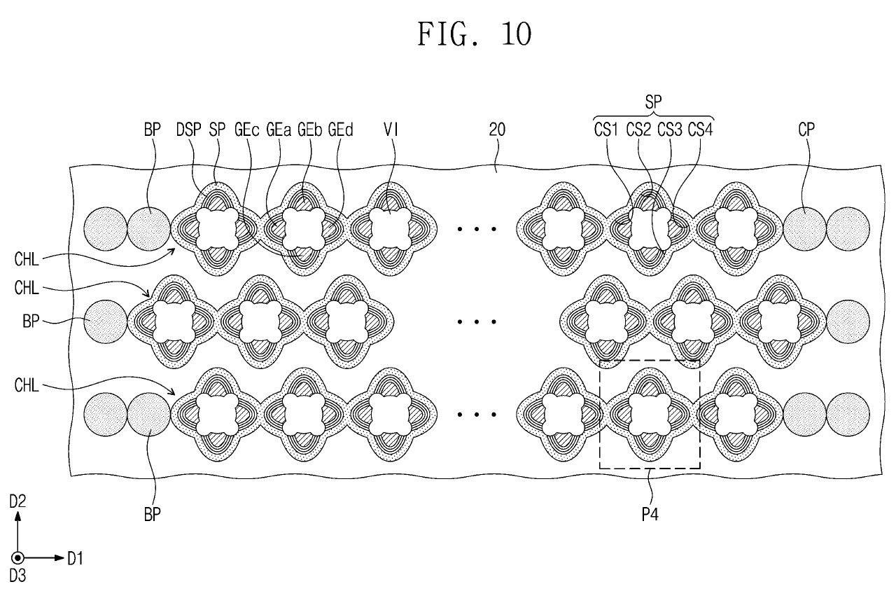

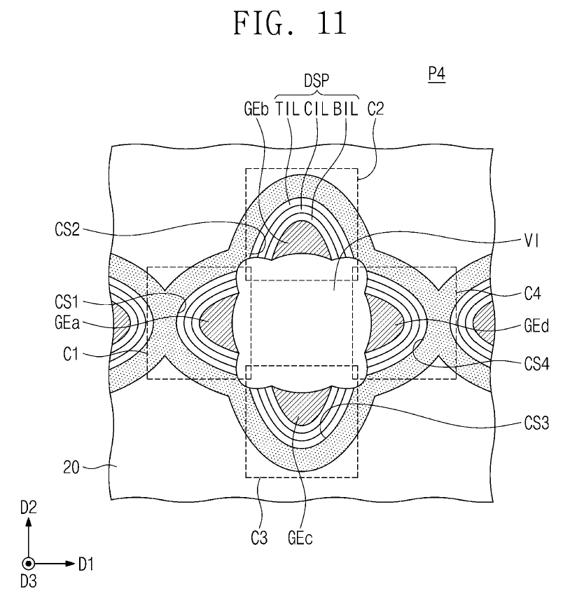

FIG. 10 is a schematic plan view of an example of a semiconductor memory device. FIG. 11 is an enlarged view of the P4 portion of FIG. 10. For simplicity of description, description of the same technical features as the semiconductor memory devices described with respect to FIGS. 2 - 5, 6A, 6B, and 7 may be omitted from the following description, and the following discussion focuses on technical features that differ from that of the semiconductor memory devices described with respect to FIGS. 2-5, 6A, 6B, and 7.

Referring to FIGS. 10 and 11, as described above, the interlayer insulating layers 10 and the channel layers CHL may be alternately stacked along the third direction D3 perpendicular to the top surface of the substrate 100. The channel layers CHL may be arranged in a zigzag shape along the second direction D2. The sacrificial patterns 20 may be disposed between the channel layers CHL adjacent to each other in the second direction D2.

Each of the channel layers CHL may include a plurality of channel patterns SP connected to each other in the first direction D1. Each of the channel patterns SP may surround portions of sidewalls of the plurality of gate electrodes GEa to GEd.

Each of the channel patterns SP may include first to fourth rounded surfaces CS1, CS2, CS3, and CS4 arranged in different directions, when viewed in a plan view. The first and fourth rounded surfaces CS1, CS4 may be opposite to each other in the first direction D1, and the second and third rounded surfaces CS2, CS3 may be opposite to each other in the second direction D2. In some implementations, a distance in the first direction D1 between the first and fourth rounded surfaces CS1, CS4 may be substantially equal to a distance in the second direction D2 between the second and third rounded surfaces CS2, CS3.

The first to fourth gate electrodes GEa to GEd, the data storage pattern DSP, and the vertical insulating pattern VI may be disposed in respective vertical holes penetrating the interlayer insulating layers 10 and the channel layers CHL alternately stacked on the substrate 100.

Referring to FIG. 11, one channel pattern SP and the first to fourth gate electrodes GEa to GEd may constitute the first, second, third, and fourth memory cells C1, C2, C3, and C4.

The first to fourth gate electrodes GEa, GEb, GEc, and GEd may penetrate each channel pattern SP in the third direction D3. The first to fourth gate electrodes GEa to GEd may be adjacent to the first to fourth rounded surface surfaces CS1 to CS4 of each channel pattern SP, respectively. The outer sidewalls of the first to fourth gate electrodes GEa to GEd may have substantially the same radius of curvature as the first to fourth rounded surfaces CS1 to CS4 of the channel pattern SP. Each channel layer CHL may surround outer sidewalls of the first to fourth gate electrodes GEa to GEd with a substantially uniform thickness.

The data storage patterns DSP may be disposed between the outer sidewalls of the first to fourth gate electrodes GEa to GEd and the first to fourth rounded surface surfaces CS1 to CS4 of each channel pattern SP, respectively. As described above, each data storage pattern DSP may include the tunnel insulating layer TIL, the charge storage layer CIL, and the blocking insulating layer BIL.

The vertical insulating pattern VI may isolate and separate the first to fourth gate electrodes GEa, GEb, GEc, and GEd from each other in each channel pattern SP.

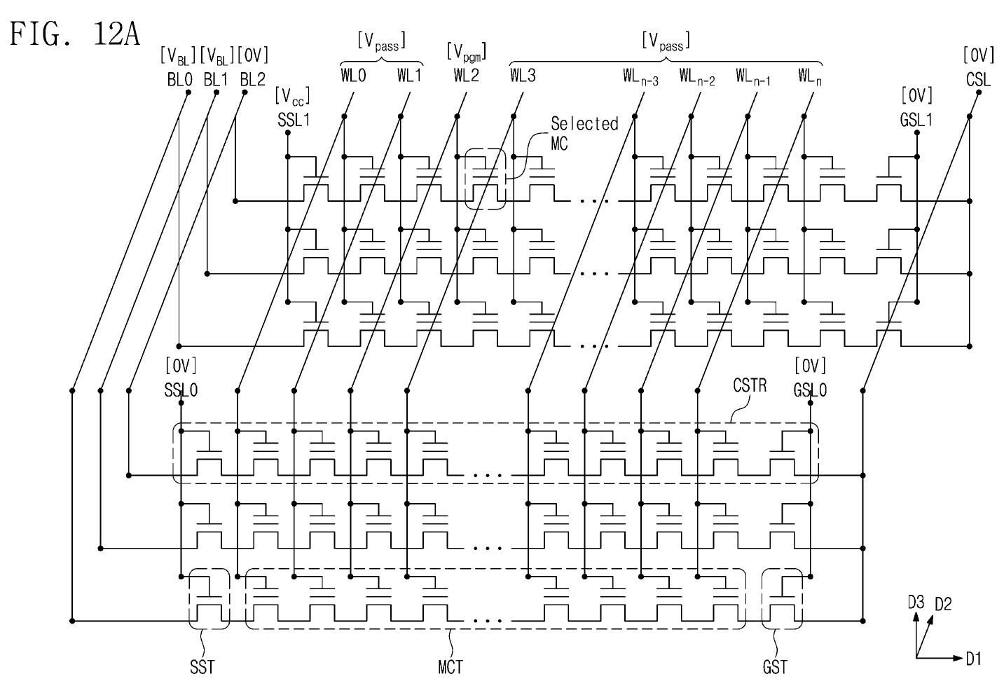

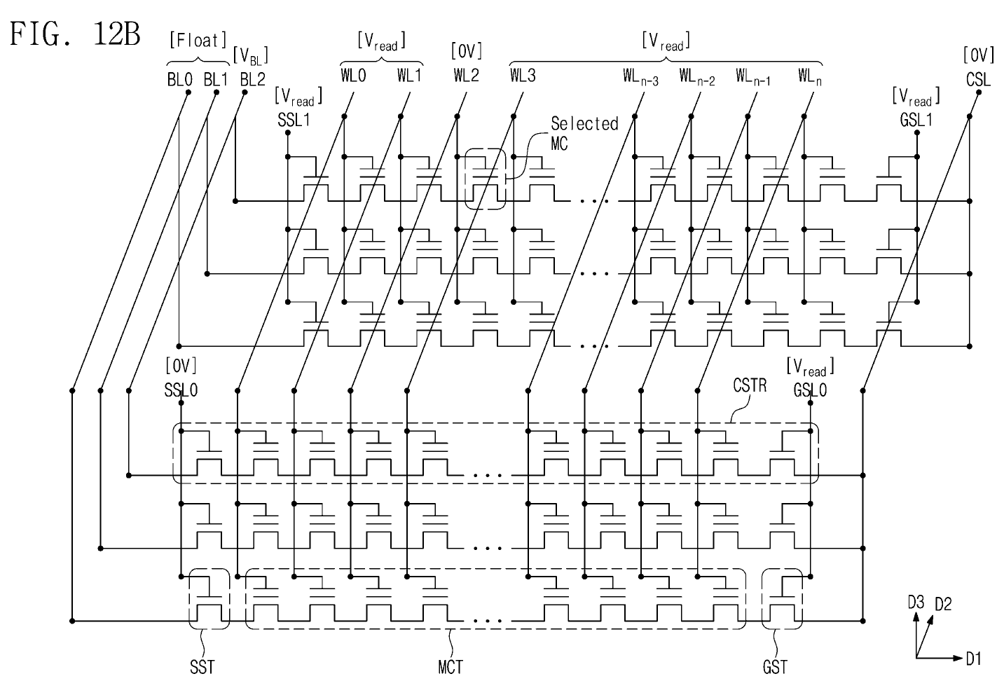

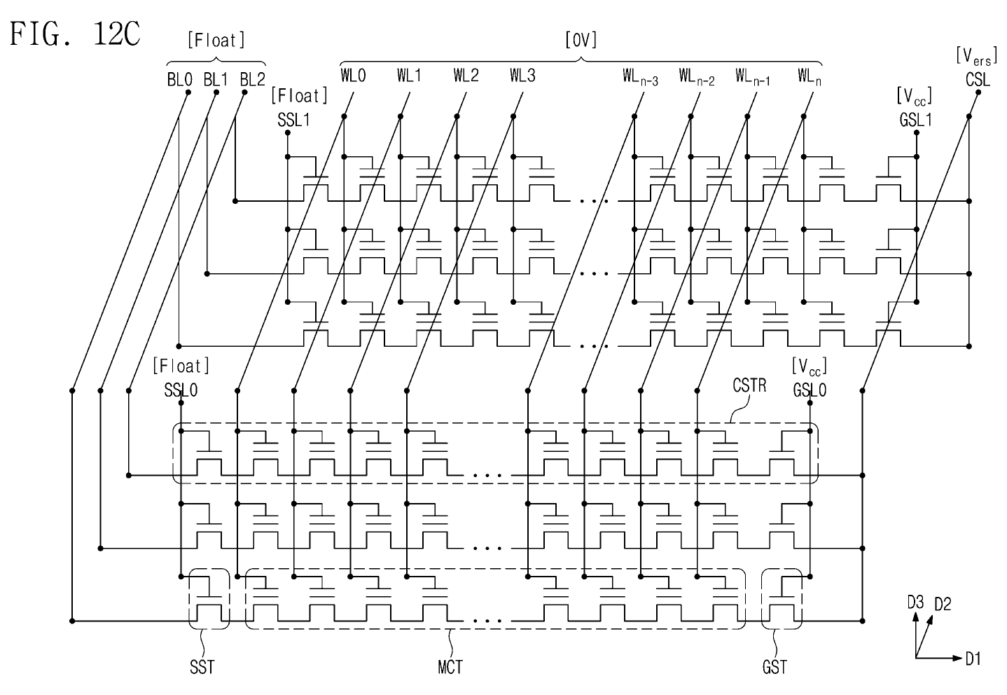

FIGS. 12A, 12B, and 12C are diagrams to illustrate an example of a method of operating a semiconductor device, e.g., a semiconductor memory device as described with respect to FIGS. 2 - 5, 6A, 6B, and 7 - 11.

FIG. 12A is a diagram for describing a program operation of a semiconductor memory device. Referring to FIG. 12A, a ground voltage Vss or 0V may be applied to a selected bit line BL2 among a plurality of bit lines BL0-BL2, and a predetermined bit line voltage V_{BL} may be applied to unselected bit lines BL0 and BL1. The ground voltage Vss or 0V may be applied to the common source lines CSL.

A power supply voltage Vcc may be applied to the selected string selection line SSL1, and the ground voltage Vss or 0V may be applied to the unselected string selection line SSL0.

The ground voltage Vss or 0V may be applied to the ground selection lines GSL0 and GSL1.

A program voltage Vpgm may be applied to the selected word line WL2, and a pass voltage Vpass may be applied to unselected word lines WL0, WL1, and WL3 to WLn. Here, the pass voltage Vpass may be selected in a range larger than the threshold voltage of the memory cell transistors MCT and smaller than the program voltage Vpgm. The program voltage Vpgm may be greater than the pass voltage Vpass. The program voltage Vpgm may be a relatively high voltage (e.g., 20 V to 40 V) compared to the read voltage Vread, the pass voltage Vpass, and a verify voltage.

In this voltage condition, an inversion region may be induced in the channel layer (CHL in FIGS. 2, 3, and 4) of the cell string CSTR including the selected memory cell (selected MC) to generate a current path. For example, the current path may be generated along the rounded surfaces CS1, CS2, CS3, and CS4 of the selected channel layer (CHL in FIGS. 2, 3, and 4).

In addition, the ground voltage Vss or 0V applied to the selected bit line BL1 may be transmitted to the channel layer (CHL in FIGS. 2, 3, and 4) adjacent to the selected word line WL2 through inversion regions generated in the channel layer (CHL in FIGS. 2, 3, and 4) by the pass voltage Vpass. Therefore, a large voltage difference is generated between the selected word line WL2 and the channel layer (CHL in FIGS. 2, 3, and 4), a Fowler-Nordheim tunneling phenomenon occurs in the selected memory cell transistor (selected MC), and data may be programmed to the selected memory cell transistor (selected MC).

FIG. 12B is a diagram for describing a read operation of a semiconductor memory device. The read operation may include sensing a current flowing between the common source line CSL and the selected bit line BL2 through the channel layer CHL (refer to FIGS. 2, 3, and 4) of a cell string CSTR including the selected memory cell transistor (selected MC). The read operation may vary in magnitude of the current depending on the data stored in the selected memory cell transistor (selected MC), and the magnitude of the current may be read in a sense amplifier.

The predetermined bit line voltage V_{BL} may be applied to the selected bit line BL2 during a read operation, and the unselected bit lines BL0 and BL1 may be electrically floated.

A read voltage Vread or the power supply voltage Vcc may be applied to the selected string selection line SSL1, and the ground voltage Vss or 0V may be applied to the unselected string selection line SSL0.

The read voltage Vread or the power supply voltage Vcc may be applied to the ground selection lines GSL0 and GSL1.

The read voltage Vread may be applied to the selected word line WL2, and a pass voltage Vpass may be applied to the unselected word lines WL0, WL1, and WL3 to WLn. Here, the read voltage Vread may be greater than a threshold voltage of the memory cell transistors MCT and may be less than the program voltage Vpgm.

Under these voltage conditions, an inversion region may be induced along the rounded surfaces CS1, CS2, CS3, and CS4 of the channel layer (CHL in FIGS. 2, 3, and 4) of the cell string CSTR including the selected memory cell transistor (selected MC) to generate a current path. In addition, the current magnitude measured in the selected bit line BL2 may be differently detected depending on data stored in the selected memory cell transistor (selected MC).

FIG. 12C is a diagram for describing a read operation of a semiconductor memory device. Referring to FIG. 12C, an erase voltage Vers may be applied to the common source line CSL during an erase operation, and the ground voltage Vss or 0V may be applied to word lines WL0 to WLn. The power supply voltage Vcc or the read voltage may be applied to the ground selection lines GSL0 and GSL1 to turn on the ground selection transistor GST.

In this voltage condition, all memory cell transistors MCT included in the memory cell strings CSTR may be erased simultaneously via the Fowler-Nordheim tunneling.

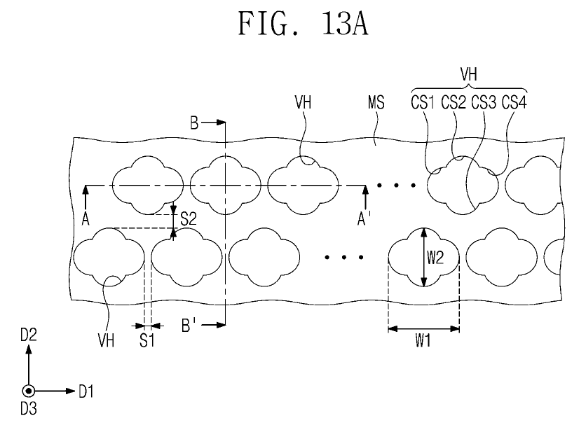

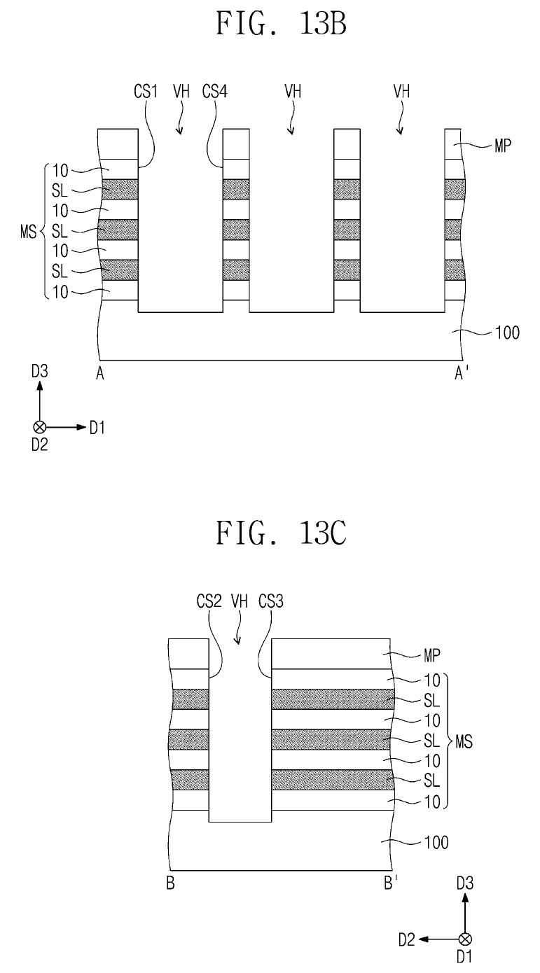

FIGS. 13A, 14A, 15A, 16A, 17A, and 18A are plan views to illustrate an example of a method of manufacturing a semiconductor memory device. FIGS. 13B, 14B, 15B, 16B, 17B, and 18B are cross-sectional views taken along lines A-A′ of FIGS. 13A - 18A. FIGS. 13C, 14C, 15C, 16C, 17C, and to 18C are cross-sectional views taken along lines B-B′ of FIGS. 13A - 18A. Although these drawings illustrate manufacture of a semiconductor device as described with respect to FIGS. 2 - 5, 6A and 6B, and 7, it will be understood that the processes disclosed are also applicable to other examples of semiconductors devices described herein.

Referring to FIGS. 13A, 13B, and 13C, interlayer insulating layers 10 and sacrificial layers SL may be alternately and repeatedly stacked on the substrate 100 to form a mold structure MS.

In the mold structure MS, the sacrificial layers SL may have substantially the same thickness, and the interlayer insulating layers 10 may have substantially the same thickness. In the mold structure MS, the sacrificial layers SL may be formed of a material that has etching selectivity with respect to the interlayer insulating layers 10. For example, the sacrificial layers SL may be formed of an insulating material different from the interlayer insulating layers 10. For example, the sacrificial layers SL may be formed of a silicon nitride layer, and the interlayer insulating layers 10 may be formed of silicon oxide layers.

The interlayer insulating layers 10 and the sacrificial layers SL may be deposited using, for example, thermal chemical vapor deposition (Thermal CVD), plasma enhanced CVD, physical chemical vapor deposition (physical CVD), or atomic layer deposition (ALD) technology.

A mask pattern MP may be formed on the uppermost interlayer insulating layer 10 of the mold structure MS. The mask pattern MP may have an opening corresponding to the vertical holes. The opening formed in the mask pattern MP may have a shape in which at least three or more circular openings are superimposed.

The mask pattern MP may be formed of an insulating material having etching selectivity with respect to the sacrificial layers SL and the interlayer insulating layers 10. The mask pattern MP may include, for example, at least one of a silicon oxide layer, a silicon oxynitride layer, or a silicon nitride layer.

Thereafter, vertical holes VH penetrating through the mold structure MS in the third direction D3 may be formed by anisotropically etching the mold structure MS using the mask pattern MP as an etching mask.

The vertical holes VH may expose sidewalls of the interlayer insulating layers 10 and the sacrificial layers SL, and may expose a top surface of the substrate 100. The top surface of the substrate 100 below the vertical holes VH may be recessed by an over-etch during an anisotropic etch. As another example, the vertical holes VH may expose the lowermost interlayer insulating layer 10.

The vertical holes VH may be two-dimensionally arranged and may be arranged in a zigzag pattern along the first direction D1.

Each of the vertical holes VH may include at least three or more rounded surfaces CS1, CS2, CS3, and CS4. The rounded surfaces CS1, CS2, CS3, and CS4 may be arranged in different directions when viewed in a plan view, and may be connected to each other to define a sidewall of each vertical hole VH. The rounded surfaces CS1, CS2, CS3, and CS4 may be arranged in different directions when viewed in a plan view. In other words, each of the vertical holes VH may have rounded inner walls.

In some implementations, each of the vertical holes VH may have a first rounded surface CS1, a second rounded surface CS2, a third rounded surface CS3, and a fourth rounded surface CS4. Here, the first rounded surface CS1 may face the fourth rounded surface CS4 in the first direction D1, and the second rounded surface CS2 may face the third rounded surface CS3 in the second direction D2.

Each of the vertical holes VH may have a first width W1 in the first direction D1, and may have a second width W2 that is less than the first width W1, in the second direction D2 that intersects the first direction D1. In addition, the vertical holes VH may be formed to be spaced apart from each other at a first interval S1 in the first direction D1, and may be formed to have a second interval S2 in the second direction D2 that is larger than the first interval S1.

In some implementations, each of the vertical holes VH may have three rounded surfaces as shown in FIGS. 8 and 9 above. In some implementations, as shown in FIGS. 10 and 11, in each of the vertical holes VH, the rounded surfaces CS1, CS2, CS3, and CS4 may be spaced apart by the same distance in the first direction D1 and the second direction D2.

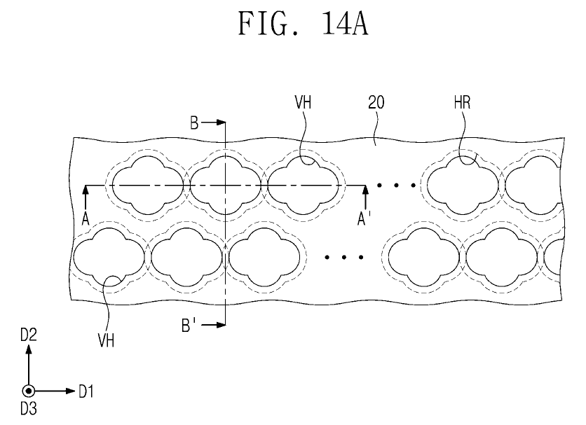

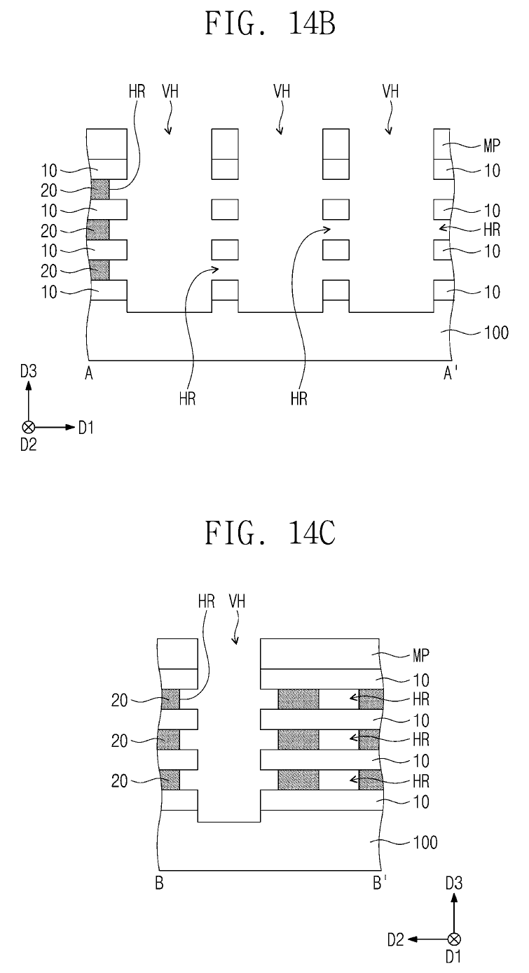

Referring to FIGS. 14A, 14B, and 14C, horizontal regions HR may be formed between vertically adjacent interlayer insulating layers 10 by isotropically etching portions of the sacrificial layers SL exposed in the vertical holes VH. The horizontal regions HR may be laterally recessed from the vertical holes VH.

Because the distance between the vertical holes VH is greater in the second direction D2 than in the first direction D1, the horizontal regions HR may be connected in the first direction D1 and may be spaced apart from each other in the second direction D2. In addition, portions of the sacrificial layers SL may remain to form sacrificial patterns 20 while forming the horizontal regions HR.

Forming the horizontal regions HR may include isotropically etching the sacrificial layers SL using an etch recipe having etch selectivity with respect to the interlayer insulating layers 10 and the substrate 100. For example, when the sacrificial layers SL are silicon nitride layers and the interlayer insulating layers 10 are silicon oxide layers, an etchant containing phosphoric acid may be used in an isotropic etching process.

As an isotropic etching process is performed on the sacrificial layers SL, the sacrificial patterns 20 may have rounded sidewalls, i.e., curved surfaces, substantially the same as (corresponding to) the vertical holes VH.

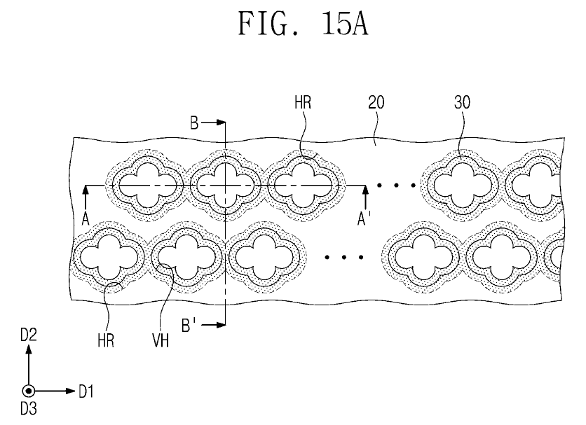

Referring to FIGS. 15A, 15B, and 15C, a semiconductor layer 30 may be deposited in the vertical holes VH to fill the horizontal regions HR.

The semiconductor layer 30 may completely fill the horizontal regions HR, and may be deposited to cover the inner walls of the vertical holes VH and the top surface of the substrate 100 with a substantially uniform thickness. The semiconductor layer 30 may define gap regions in the vertical holes VH. The semiconductor layer 30 may be formed of a polycrystalline or amorphous polysilicon layer.

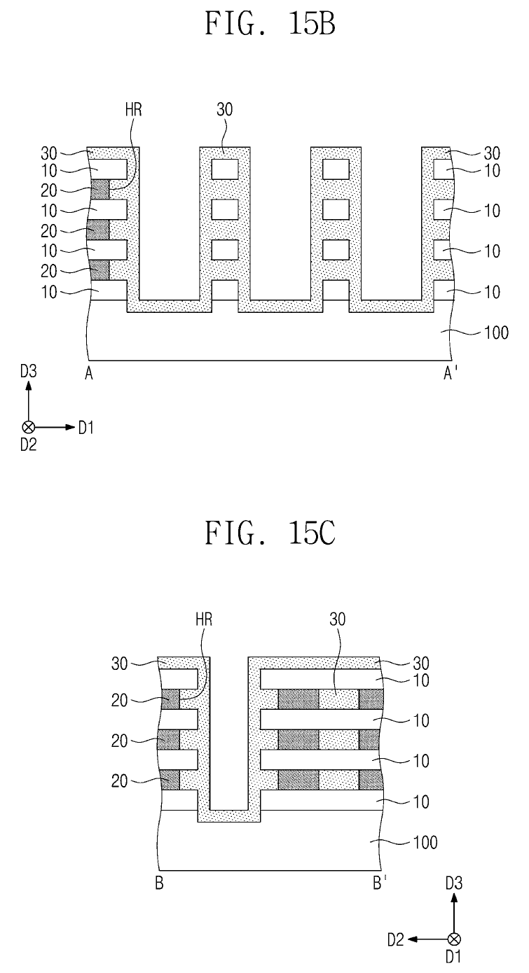

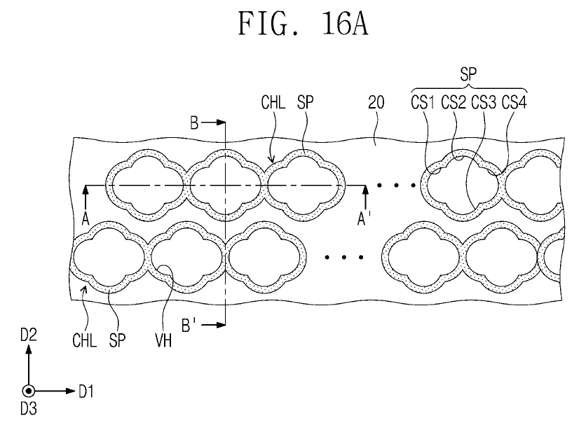

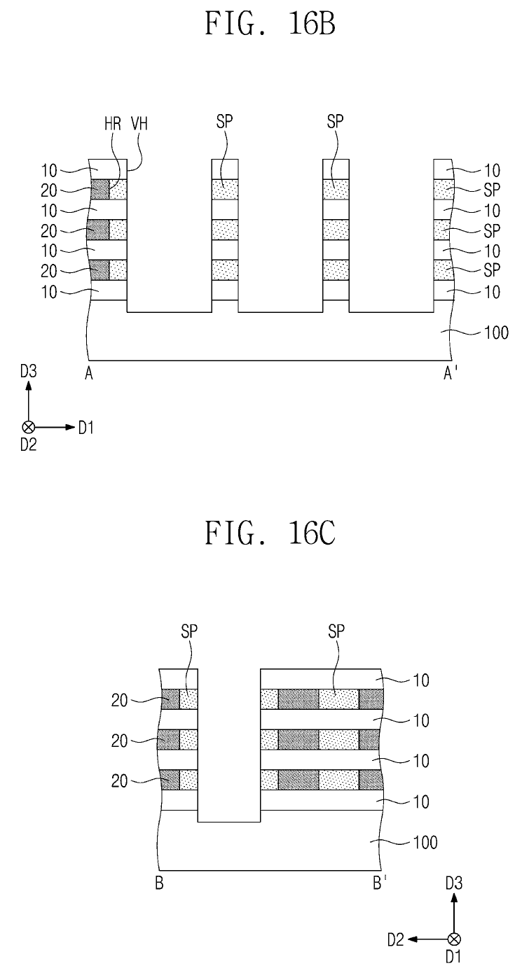

Referring to FIGS. 16A, 16B, and 16C, the channel patterns SP may be formed in the horizontal regions HR, respectively, by removing the semiconductor layer 30 from the inner walls of the vertical holes VH.

In some implementations, forming the channel patterns SP may include performing an isotropic etching process on the semiconductor layer 30 through gap regions defined by the semiconductor layer 30. The channel patterns SP may be vertically separated from each other by an isotropic etching process on the semiconductor layer 30.

In some implementations, forming the channel patterns SP may include forming an etching mask pattern having an opening corresponding to the vertical holes VH on the uppermost interlayer insulating layer, and then performing an anisotropic etching process on the semiconductor layer 30.

As the channel patterns SP are formed, sidewalls of the interlayer insulating layers 10 may be exposed to the vertical holes VH. Each of the channel patterns SP thus formed may be connected to each other without a boundary surface in the first direction D1, and may be in contact with sidewalls of the sacrificial patterns 20. For example, each of the channel patterns SP may have rounded surfaces CS1, CS2, CS3, and CS4 substantially the same as (e.g., having a same shape as) the rounded surfaces formed in the vertical holes VH. In addition, each of the channel patterns SP may have a substantially uniform thickness in a horizontal direction parallel to the top surface of the substrate 100.

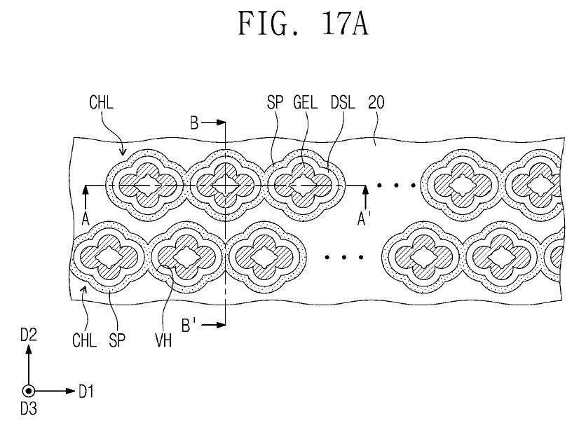

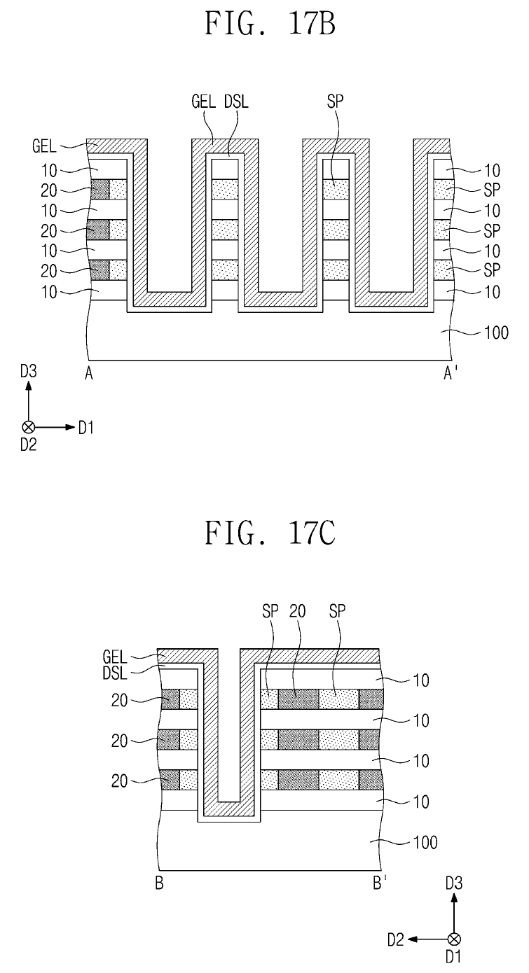

Referring to FIGS. 17A, 17B, and 17C, after forming the channel patterns SP, a data storage layer DSL and a gate conductive layer GEL may be sequentially deposited in the vertical holes VH.

The data storage layer DSL may be deposited on the bottom surfaces and inner walls of the vertical holes VH with a uniform thickness using a chemical vapor deposition (CVD) or atomic layer deposition (ALD) method. The data storage layer DSL may include a blocking insulating layer, a charge storage layer, and a tunneling insulating layer sequentially stacked in the vertical holes VH.

The gate conductive layer GEL may be deposited with a uniform thickness in the vertical holes VH in which the data storage layer DSL is formed. The gate conductive layer GEL may fill parts of the vertical holes VH. The gate conductive layer GEL may be formed using a chemical vapor deposition (CVD) or an atomic layer deposition (ALD) method.

The gate conductive layer GEL may include, for example, at least one selected from a doped semiconductor (e.g., doped silicon, etc.), a metal (e.g., tungsten, copper, aluminum, etc.), an electrically conductive metal nitride (e.g., titanium nitride, tantalum nitride, etc.), or a transition metal (e.g., titanium, tantalum, etc.).

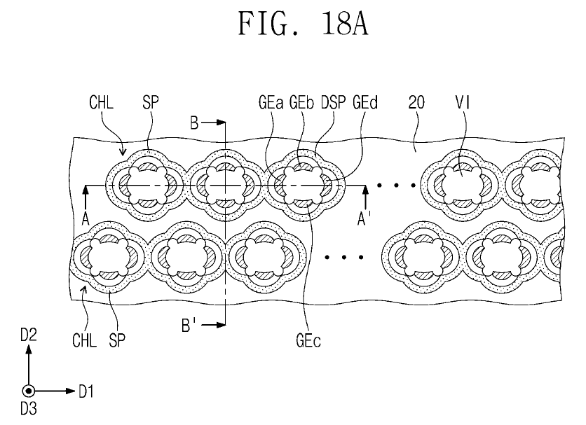

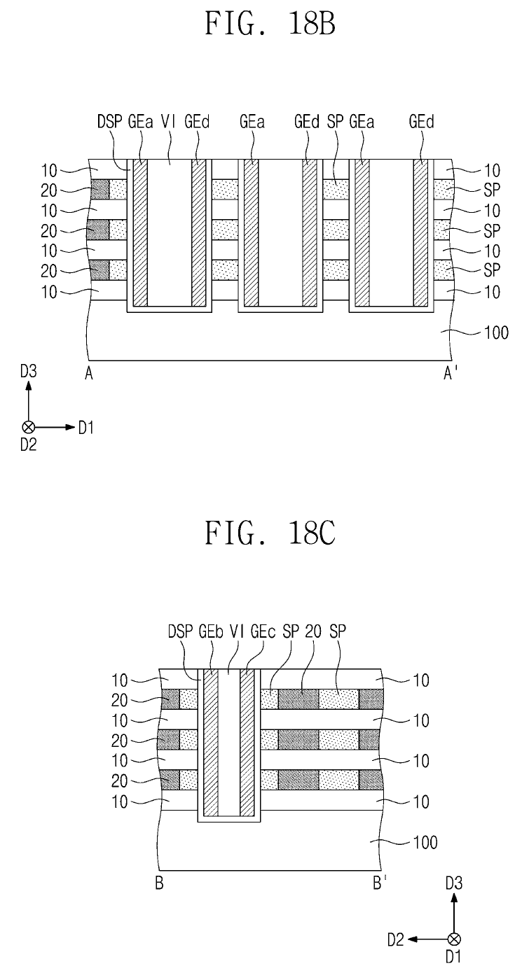

Referring to FIGS. 18A, 18B, and 18C, the data storage layer DSL and the gate conductive layer GEL may be etched and planarized until the uppermost interlayer insulating layer 10 is exposed.

Thereafter, a trimming process of separating the gate conductive layer GEL into the first to fourth gate electrodes GEa to GEd in each of the vertical holes VH may be performed. In some implementations, the trimming process may include removing portions of the gate conductive layer GEL through an isotropic etch process on the gate conductive layer GEL deposited in the vertical holes VH having rounded surfaces. In some implementations, the first to fourth gate electrodes GEa to GEd may be formed in each vertical hole VH by performing a patterning process on the gate conductive layer GEL.

After the first to fourth gate electrodes GEa to GEd are formed, portions of the data storage layer exposed between the first to fourth gate electrodes GEa and GEd may be removed to form data storage patterns DSP separated from each other in each vertical hole VH.

After the first to fourth gate electrodes GEa to GEd are formed, a vertical insulating pattern VI may be filled in the vertical holes VH. Forming the vertical insulating pattern VI may include depositing an insulating layer filling the vertical holes VH in which the first to fourth gate electrodes GEa to GEd are formed, and then etching and planarizing the insulating layer to expose the uppermost interlayer insulating layer 10.

After forming the vertical insulating pattern VI, bit line pad patterns BP connected to the first ends of the channel layers CHL may be formed, as shown in FIGS. 2, 3, and 4.

Forming the bit line pad patterns BP may include forming vertical contact holes penetrating a staircase portion of the mold structure MS, isotropically etching portions of sacrificial layers exposed to the vertical contact holes to form recess regions, and depositing an impurity-doped semiconductor material in the recess regions to connect with both ends of the channel patterns, as with forming the horizontal regions HR and the channel patterns SP described above. Since the bit line pad patterns BP are formed in the step portion of the mold structure, the length of the bit line pad pattern BP in the first direction D1 may decrease as the distance from the top surface of the substrate 100 increases.

In addition, common source pad patterns CP may be formed to be connected to the second ends of the channel layers CHL. Forming the common source pad pattern CP may be similar to forming the bit line pad patterns BP.

Then, the insulating layer 110 may be formed to cover the stack ST and the gate electrodes SGE, GEa to GEd, and GGE, and the word lines WL0 to WL4n may be formed on the insulating layer 110 to be connected to the gate electrodes GEa to GGEd through the word line contacts CT.

According to implementations of the present disclosure, since the channel layers are parallel to the top surface of the substrate and are stacked in a vertical direction perpendicular to the top surface of the substrate, it is possible to reduce the size of the semiconductor memory device in the vertical direction.

In some implementations, since the gate electrodes connected with the word lines are perpendicular to the top surface of the substrate, it may be easier to increase the number of stacked memory cells of the semiconductor memory device. In addition, an interconnection between the word lines and the peripheral circuitry may be formed more easily.

Further, in some implementations, since a plurality of gate electrodes may be formed in a single vertical hole, the integration of the semiconductor memory device may be further improved.

According to some implementations, a method of manufacturing a semiconductor memory device may include: forming a mold structure in which interlayer insulating layers and sacrificial layers are alternately stacked on a substrate; forming a plurality of vertical holes penetrating the mold structure in a first direction perpendicular to a top surface of the substrate, wherein each of the vertical holes includes at least three or more rounded surfaces; etching portions of the sacrificial layer exposed in the vertical holes to form horizontal regions connected to each other in a second direction parallel to the top surface of the substrate; forming channel patterns in the horizontal regions; after forming the channel patterns, sequentially depositing a data storage layer and a gate conductive layer in the vertical holes; and separating the gate conductive layer in each of the vertical hole to form gate electrodes adjacent to the rounded surfaces, respectively.

In some implementations, forming the channel patterns may include: depositing a semiconductor layer in the vertical holes to fill the horizontal regions; and removing the semiconductor layer on inner walls of the vertical holes to leave portions of the semiconductor layer in the horizontal regions.

In some implementations, the channel patterns located at the same distance from the top surface of the substrate may be connected to each other in the second direction.

In some implementations, the rounded surfaces of each of the vertical holes may be arranged in different directions.

In some implementations, the rounded surfaces of each of the vertical holes may be arranged in different directions.

In some implementations, each of the vertical holes may have a first width in the second direction and a second width in a third direction parallel to the top surface of the substrate and intersecting the second direction, wherein the first width is greater than the second width.

In some implementations, the vertical holes may be spaced apart from one another at a first interval in the second direction and spaced apart from each other by a second interval in a third direction parallel to the top surface of the substrate, wherein the second interval may be greater than the first interval.

In some implementations, forming the horizontal regions may include: forming sacrificial patterns between the vertical holes adjacent in a third direction parallel to a top surface of the substrate.

In some implementations, forming the gate conductive layer may include: defining a gap region in the respective vertical holes; and isotropically etching the gate conductive layer through the gap region to form the gate electrodes.

In some implementations, after forming the gate electrodes in each of the vertical holes, forming a vertical insulating pattern that fills the vertical holes may further be included.

In some implementations, depositing the data storage layer may include: depositing a tunneling insulating layer, a charge storage layer, and a blocking insulating layer on inner walls of the vertical holes in turn.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the present disclosure has been described with reference to examples thereof, it will be apparent to those of ordinary skill in the art that various changes and modifications may be made thereto without departing from the spirit and scope of the present disclosure as set forth in the following claims.

What is claimed is:

1. A semiconductor memory device comprising:
a substrate;
channel layers on the substrate, arranged along a first direction perpendicular to a top surface of the substrate, and spaced apart from one another along the first direction,
wherein each of the channel layers includes a plurality of channel patterns arranged along a second direction parallel to the top surface of the substrate, wherein channel patterns of the plurality of channel patterns that are adjacent to one another along the second direction are in contact with one another, and wherein each channel pattern of the plurality of channel patterns comprises at least three rounded surfaces;
a plurality of gate electrodes extending through the channel layers in the first direction, wherein each gate electrode of the plurality of gate electrodes is adjacent to a rounded surface of the at least three rounded surfaces of each channel pattern; and
data storage patterns between the plurality of gate electrodes and the plurality of channel patterns.

2. The semiconductor memory device of claim 1, wherein the at least three rounded surfaces of each channel pattern protrude in different directions, in a plan view.

3. The semiconductor memory device of claim 1, wherein portions of the plurality of channel patterns are disposed between and in contact with pairs of data storage patterns that correspond to pairs of channel patterns adjacent to one another along the second direction.

4. The semiconductor memory device of claim 1, wherein each of the channel patterns has a uniform thickness parallel to the top surface of the substrate.

5. The semiconductor memory device of claim 1, wherein the channel layers are first channel layers, and
wherein the semiconductor memory device comprises:
second channel layers arranged along the first direction and spaced apart from the first channel layers in a third direction parallel to the top surface of the substrate; and
sacrificial patterns between the first channel layers and the second channel layers in the third direction.

6. The semiconductor memory device of claim 5, comprising:
interlayer insulating layers extending between sacrificial patterns, of the sacrificial patterns, that are adjacent to each other in the first direction and between first channel layers, of the first channel layers, that are adjacent to each other in the first direction.

7. The semiconductor memory device of claim 1, comprising:
a vertical insulating pattern extending along the first direction and insulating, from one another, gate electrodes, of the plurality of gate electrodes, that are adjacent to different rounded surfaces of the at least three rounded surfaces of each channel pattern.

8. The semiconductor memory device of claim 1, comprising:
a plurality of word lines respectively connected to the plurality of gate electrodes,
wherein the plurality of word lines intersect the channel layers and extend along a fourth direction, and
wherein the fourth direction is parallel to the top surface of the substrate and different from the second direction.

9. The semiconductor memory device of claim 1, wherein the plurality of gate electrodes comprise a metal material.

10. The semiconductor memory device of claim 1, wherein each of the data storage patterns includes a tunnel insulating layer, a charge storage layer, and a blocking insulating layer sequentially stacked on the at least three rounded surfaces of the channel patterns.

11. A semiconductor memory device comprising:
a substrate;
a stack on the substrate, the stack including channel layers divided into sets of channel layers spaced apart from one another in a third direction parallel to a top surface of the substrate, wherein channel layers of each set of channel layers are arranged along a first direction perpendicular to the top surface of the substrate and spaced apart from each other in the first direction;
a plurality of gate electrodes extending through the channel layers of the stack in the first direction; and
data storage patterns between the plurality of gate electrodes and the channel layers of the stack,
wherein the stack comprises:
interlayer insulating layers between channel layers, of the channel layers of each set of channel layers, that are adjacent to each other in the first direction; and
sacrificial patterns between the sets of channel layers, of the sets of channel layers, that are adjacent to each other in the third direction,
wherein each channel layer of the channel layers of the stack includes a plurality of channel patterns arranged along a second direction parallel to the top surface of the substrate, wherein channel patterns of the plurality of channel patterns that are adjacent to one another along the second direction are in contact with one another, and wherein each channel pattern of the plurality of channel patterns comprises at least three rounded surfaces, and
wherein each gate electrode of the plurality of gate electrodes is adjacent to a rounded surface of the at least three rounded surfaces of each channel pattern of the plurality of channel patterns of each channel layer.

12. The semiconductor memory device of claim 11, wherein, in each channel pattern of the plurality of channel patterns of each channel layer, the at least three rounded surfaces protrude in different directions, in a plan view.

13. The semiconductor memory device of claim 11, wherein the data storage patterns extend along the first direction between the plurality of gate electrodes and the plurality of channel patterns of each channel layer and between the plurality of gate electrodes and the interlayer insulating layers.

14. The semiconductor memory device of claim 11, wherein each channel pattern of the plurality of channel patterns of each channel layer has a uniform thickness parallel to the top surface of the substrate.

15. The semiconductor memory device of claim 11, wherein the channel layers of the stack are in contact with the sacrificial patterns.

16. The semiconductor memory device of claim 11, comprising:
a plurality of word lines connected to the plurality of gate electrodes,
wherein the plurality of word lines intersect the channel layers and extend in a fourth direction parallel to the top surface of the substrate, and
wherein the fourth direction is different from the second direction and the third direction.

17. A semiconductor memory device comprising:
a substrate;
channel layers on the substrate, the channel layers divided into sets of channel layers spaced apart from one another in a third direction parallel to a top surface of the substrate, wherein channel layers of each set of channel layers are arranged along a first direction perpendicular to the top surface of the substrate and spaced apart from each other in the first direction,
wherein each of the channel layers includes a plurality of channel patterns arranged along a second direction parallel to the top surface of the substrate, wherein channel patterns of the plurality of channel patterns that are adjacent to one another along the second direction are in contact with one another, and
wherein each channel pattern of the plurality of channel patterns comprises first, second, third, and fourth rounded surfaces protruding in different directions in a plan view;
sacrificial patterns between the sets of channel layers, of the sets of channel layers, that are adjacent to each other in the third direction ;
interlayer insulating layers between channel layers, of the channel layers of each set of channel layers, that are adjacent to each other in the first direction, and between the sacrificial patterns;
for each channel pattern of the plurality of channel patterns of each of the channel layers:
first, second, third, and fourth gate electrodes extending through the channel pattern in the first direction, wherein the first to fourth gate electrodes are disposed adjacent to the first to fourth rounded surfaces of the channel pattern, respectively,
a data storage pattern between the first to fourth gate electrodes and the channel pattern, and
a vertical insulating pattern that insulates the first to fourth gate electrodes from one another;
bit lines respectively connected to first ends of the channel layers; and
a common source line commonly connected to second ends of the channel layers.

18. The semiconductor memory device of claim 17, wherein the plurality of channel patterns of a first channel layer of the channel layers comprises a first channel pattern and a second channel pattern that are adjacent to each other in the second direction,
wherein portions of the first channel pattern and second channel pattern are between the first gate electrode of the first channel pattern and the fourth gate electrode of the second channel pattern.

19. The semiconductor memory device of claim 17, for each channel pattern of the plurality of channel patterns of each of the channel layers:
the first and fourth gate electrodes are spaced apart from each other in the second direction, and
the second and third gate electrodes are spaced apart from each other in the third direction.

20. The semiconductor memory device of claim 17, further comprising:
a plurality of word lines connected to the first to fourth gate electrodes of the plurality of channel patterns of each of the channel layers,
wherein the plurality of word lines intersect the channel layers and extend along a fourth direction parallel to the top surface of the substrate, and
wherein the fourth direction is different from the second direction and the third direction.
